(19) United States
(12) Patent Application Publication
(10) Pub. No.: US 2014/0346540 A1
(43) Pub. Date: Nov. 27, 2014

(54) LIGHT EMITTING DIODE DIE

(71) Applicant: ADVANCED OPTOELECTRONIC TECHNOLOGY, INC., Hsinchu Hsien (TW)

(72) Inventors: Tzu-Chien HUNG, Hukou (TW); Chia-Hui SHEN, Hukou (TW); Chien-Chung PENG, Hukou (TW)

(73) Assignee: ADVANCED OPTOELECTRONIC TECHNOLOGY, INC., Hsinchu Hsien (TW)

(21) Appl. No.: 14/279,300

(22) Filed: May 15, 2014

(30) Foreign Application Priority Data
May 22, 2013 (CN) 201310191843X

(51) Int. Cl. H01L 33/58; H01L 33/22; H01L 33/42

(52) U.S. Cl. CPC H01L 33/58; H01L 33/42; H01L 33/22
USPC 257/94

(57) ABSTRACT

A light emitting diode (LED) die includes a first semiconductor layer, a second semiconductor layer, an active layer interposed between the first and second semiconductor layers, a transparent electrically conductive layer formed on the second semiconductor layer, and a passivation layer formed on the transparent electrically conductive layer. A first electrode is electrically connected with the first semiconductor layer, and a second electrode is is electrically connected with the second semiconductor layer. The transparent electrically conductive layer is made of tin doped indium oxide. The passivation layer is made of silicon nitride having a refractive index close to that of the transparent electrically conductive layer.

### TECHNICAL FIELD

The present disclosure relates generally to light emitting diode (LED) dies, and particularly to an LED die having high light extraction efficiency.

### DESCRIPTION OF RELATED ART

LEDs are solid state light emitting devices formed of semiconductors. LEDs are more stable and reliable than other conventional light sources such as incandescent bulbs. Thus, LEDs are being widely used in various fields such as numeral/character displaying elements, signal lights, and lighting and display devices.

A typical LED die includes a first semiconductor layer, an active layer, a second semiconductor layer, a transparent electrically conductive layer, and a passivation layer formed on the a substrate in sequence. However, the passivation layer is made of silicon oxide having a refractive index in a range between 1.44 and 1.55, while the transparent electrically conductive layer is made of tin doped indium oxide (ITO) having a refractive index in a range between 1.8 and 2.1. When a forward bias is applied to such LED die, light generated from the active layer is mostly confined inside the LED die due to total internal reflection at an interface between the transparent electrically conductive layer and the passivation layer, thereby decreasing the light extraction efficiency of the LED die.

What is needed therefore is an LED die which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an illustrative, cross-sectional view of an LED die in accordance with a first embodiment of the present disclosure.

FIG. 2 is an illustrative, cross-sectional view of an LED die in accordance with a second embodiment of the present disclosure.

### DETAILED DESCRIPTION

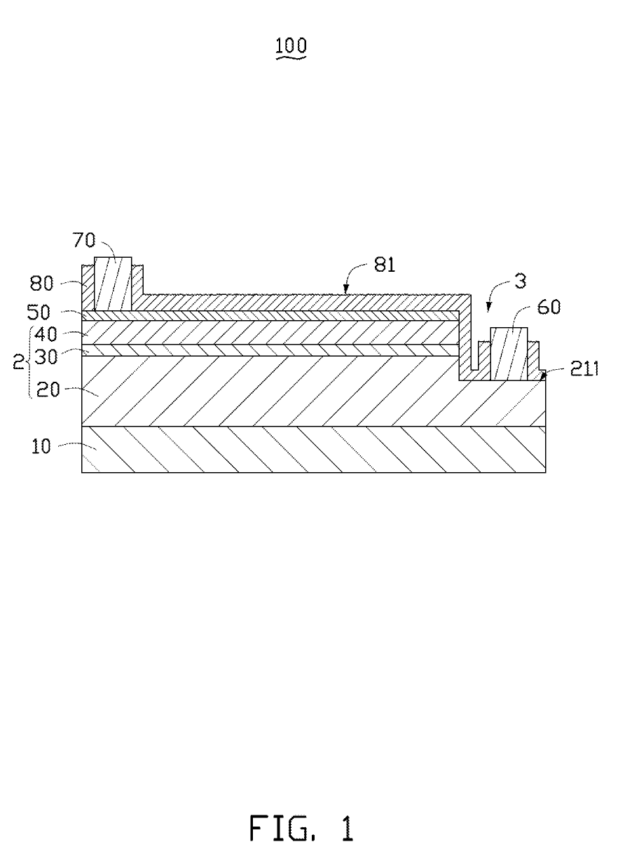

Referring to FIG. 1, an LED die 100 in accordance with a first embodiment of the present disclosure is illustrated. The LED die 100 includes a substrate 10, an epitaxial layer 2 formed on the substrate 10, and a transparent electrically conductive layer 50 formed on the epitaxial layer 2. The epitaxial layer 2 includes a first semiconductor layer 20, an active layer 30 and a second semiconductor layer 40 formed on the substrate 10 in sequence. A first type electrode 60 is disposed on the first semiconductor layer 20 of the epitaxial layer 2. A second type electrode 70 is disposed on a top surface of the transparent electrically conductive layer 50 distant from the substrate 10. A passivation layer 80 extends between the first and second electrodes 60, 70. In the depicted embodiment, the passivation layer 80 is disposed on a top of the LED die 100.

In the present embodiment, the first semiconductor layer 20 is an N-type semiconductor for supplying electrons, the second semiconductor layer 40 is a P-type semiconductor for supplying holes, and the electrons and the holes are coupled together in the active layer 30 to thereby emit light therefrom.

The LED die 100 defines a trench 3 therein. The trench 3 extends downwardly through the transparent electrically conductive layer 50, the second semiconductor layer 40, and the active layer 30, into the first semiconductor layer 20, thereby exposing a part of the first semiconductor layer 20. The exposed part of the first semiconductor layer 20 has an exposed top surface 211. The trench 3 is formed via etching or machining.

In the present embodiment, the first type electrode 60 is an N-type electrode corresponding to the first semiconductor layer 20. The first type electrode 60 is directly formed on the exposed top surface 211 of the first semiconductor layer 20. The second type electrode 70 is a P-type electrode 70 corresponding to the second semiconductor layer 40. The second type electrode 70 is directly formed on the transparent electrically conductive layer 50.

The passivation layer 80 covers the transparent electrically conductive layer 50, sides of the second semiconductor layer 40 and the active layer 30 defining the trench 3 and the exposed part including the exposed surface 211 of the first semiconductor layer 20. The transparent electrically conductive layer 50 is made of tin doped indium oxide. The passivation layer 80 is made of silicon nitride. A refractive index of the passivation layer 80 is close to that of the transparent electrically conductive layer 50. In this embodiment, the refractive index of the transparent electrically conductive layer 50 is in a range between 1.8 and 2.1, and the refractive index of the passivation layer 80 is in a range between 1.8 and 2.0. As the refractive index of the passivation layer 80 is close to that of the transparent electrically conductive layer 50, when a forward bias is applied to the LED die 100, light generated from the active layer 30 is mostly extracted out of the LED die 100, thereby improving the light extraction efficiency of the LED die 100.

A top surface 81 of the passivation layer 80 distant from the substrate 10 is roughened. A surface roughness Ra of the top surface 81 is in a range between 0.1 micrometer and 1 micrometer, thereby enhancing the light extraction efficiency of the

LED die 100. Preferably, the surface roughness Ra of the top surface 81 is in a range between 0.1 micrometer and 0.5 micrometer.

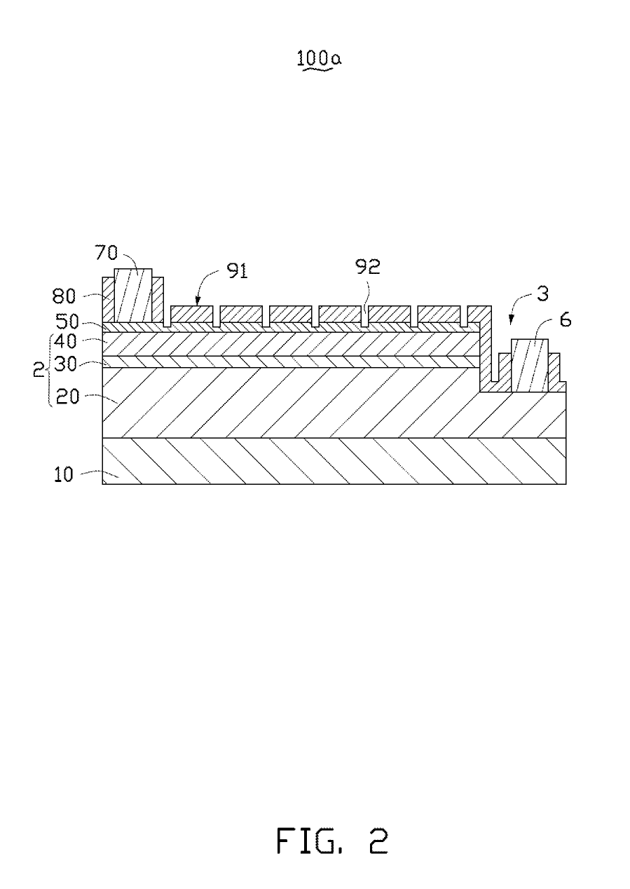

Referring to FIG. 2, an LED die 100a in accordance with a second embodiment of the present disclose is shown. Different from the LED die 100 shown in FIG. 1, the LED die 100a in FIG. 2 further defines a plurality of light guide channels 92 therein.

Each light guide channel 92 penetrates though the passivation layer 80 to partially expose the transparent electrically conductive layer 50. The passivation layer 80 is divided into a plurality of individual parts 91 by the light guide channels 92.

The light guide channels 92 each extend through the passivation layer 80 into the transparent electrically conductive layer 50. The light guide channels 92 are equally spaced from each other. In the present embodiment, each light guide channel 92 has a configuration of a round blind hole, wherein the light guide channels 92 have the same depths, and a bore diameter of each light guide channel 92 is in a range of 5 to 15 micrometers and preferably the bore diameter is about 10 micrometers. In another embodiment, the bore diameter of each light guide channel 92 can be in a range of 0.3 to 0.7 micrometer and preferably the bore diameter can be about 0.5 micrometer.

When a forward bias is applied to the LED die 100a, a part of light generated from the active layer 30 directly exits from the transparent layer 50 into ambient air via the light guide channels 92 without being blocked by the passivation layer 80, thereby improving a light extraction efficiency of the LED die 100a.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A light emitting diode (LED) die comprising:
a first semiconductor layer for supplying electrons;
a second semiconductor layer for supplying holes, the second semiconductor layer being different from the first semiconductor layer;
an active layer interposed between the first and second semiconductor layers, the active layer receiving the electrons and the holes, and emitting light in response to coupling between the electrons and the holes;
a transparent electrically conductive layer formed on the second semiconductor layer;
a passivation layer formed on the transparent electrically conductive layer;
a first electrode in electrical connection with the first semiconductor layer; and
a second electrode in electrical connection with the second semiconductor layer;
wherein the transparent electrically conductive layer is made of tin doped indium oxide, and the passivation layer is made of silicon nitride having a refractive index close to that of the transparent electrically conductive layer.

2. The LED die of claim 1, further comprising a trench extending downwardly through the transparent electrically conductive layer, the second semiconductor layer, the active layer to the first semiconductor layer, thereby exposing a part of the first semiconductor layer, the first electrode being mounted on the exposed part of the first semiconductor layer to electrically connect with the first semiconductor layer.

3. The LED die of claim 2, wherein the first semiconductor layer is an N-type semiconductor layer, and the second semiconductor layer is a P-type semiconductor layer.

4. The LED die of claim 3, wherein the first electrode is an N-type electrode in direct contact with an exposed top surface of the exposed part of the first semiconductor layer, and the second electrode is a P-type electrode in direct contact with a top surface of the transparent electrically conductive layer which is distant from the second semiconductor layer.

5. The LED die of claim 4, wherein the passivation layer extends between the first electrode and the second electrode.

6. The LED die of claim 5, wherein the passivation layer covers the transparent electrically conductive layer, sides of the second semiconductor layer and the active layer defining the trench and the exposed part including the exposed top surface of the first semiconductor layer.

7. The LED die of claim 1, wherein a top surface of the passivation layer distant from the second semiconductor layer is roughened.

8. The LED die of claim 7, wherein a surface roughness Ra of the top surface of the passivation layer is in a range between 0.1 micrometer and 1 micrometer.

9. The LED die of claim 8, wherein the surface roughness Ra of the top surface of the passivation layer is in a range between 0.1 micrometer and 0.5 micrometer.

10. The LED die of claim 1, further comprising a plurality of light guide channels, each light guide channel penetrating through the passivation layer to partially expose the transparent electrically conductive layer.

11. The LED die of claim 10, wherein each light guide channel extends into the transparent electrically conductive layer.

12. The LED die of claim 10, wherein the passivation layer is divided into a plurality of individual parts by the light guide channels.

13. The LED die of claim 12, wherein the light guide channels are equally spaced from each other.

14. The LED die of claim 10, wherein the light guide channels have the same depths.

15. The LED die of claim 10, wherein each light guide channel has a configuration of a round blind hole.

16. The LED die of claim 15, wherein a bore diameter of each light guide channel is in a range of 5 to 15 micrometers.

17. The LED die of claim 16, wherein the bore diameter of each light guide channel is 10 micrometers.

18. The LED die of claim 15, wherein a bore diameter of each light guide channel is in a range of 0.3-0.7 micrometer.

19. The LED die of claim 1, wherein a refractive index of the transparent electrically conductive layer is in a range between 1.8 and 2.1.

20. The LED die of claim 19, wherein a refractive index of the passivation layer is in a range between 1.8 and 2.0.
